(19) United States
(12) Patent Application Publication
(10) Pub. No.: US 2020/0201170 A1
(43) Pub. Date: Jun. 25, 2020

(54) SEMICONDUCTOR DEVICE AND METHOD FOR FORMING THE SAME

(71) Applicant: SK hynix Inc., Gyeonggi-do (KR)

(72) Inventor: Woo Yung JUNG, Seoul (KR)

(21) Appl. No.: 16/503,055

(22) Filed: Jul. 3, 2019

(30) Foreign Application Priority Data
Dec. 19, 2018 (KR) 10-2018-0164719

(51) Int. Cl. G03F 7/00; G03F 7/09; H01L 21/027

(52) U.S. Cl. CPC G03F 7/0002; H01L 21/0274; G03F 7/0035; G03F 7/094

(57) ABSTRACT

A semiconductor device and a method for forming the same are disclosed. The semiconductor device includes a transfer-receiving substrate having a high region and a low region that are different in top-surface height from each other, a transfer-receiving pattern layer formed over the high region and the low region of the transfer-receiving substrate, in a manner that a top surface of the transfer-receiving pattern layer in the high region is planarized and a top surface of the transfer-receiving pattern layer in the low region is provided with a concave-convex pattern, and a planarization layer formed to gapfill the concave-convex pattern in a manner that a top surface of the planarization layer in the high region and a top surface of the planarization layer in the low region are planarized at a substantially same level.

### CROSS-REFERENCE TO RELATED APPLICATION

This application claims priority under 35 U.S.C. §119(a) to Korean patent application No. 10-2018-0164719, filed on Dec. 19, 2018, the disclosure of which is incorporated in its entirety by reference herein.

### BACKGROUND OF THE INVENTION

### 1. Technical Field

Embodiments of the present disclosure generally relate to a semiconductor device, and more particularly to a semiconductor device including a planarization layer formed by nanoimprint lithography (NIL) technology based on spin coating, and a method for forming the same.

### 2. Related Art

A photolithography process is a conventional fine-structure (microstructure) fabrication technology for printing and forming complicated integrated circuit (IC) patterns on a semiconductor substrate coated with a photoresist thin film. The size of the formed pattern may be limited by an optical diffraction phenomenon, and resolution of the pattern may depend upon a thickness of a photoresist film and a wavelength of a light source. Therefore, generally, to form a smaller size fine pattern in proportion to the increasing integration degree of constituent elements of a semiconductor device, exposure technology based on a short-wavelength light source is needed.

However, conventional short-wavelength light sources have difficulty in forming ultra-fine patterns having a size of 50 nm or less.

In order to address the above-mentioned photolithography limitations, various lithography technologies have been widely used, for example, extreme ultraviolet (EUV) lithography technology well known as next generation lithography (NGL), X-ray lithography technology, ion-beam projection lithography technology, electron-beam lithography technology, etc. Existing EUV lithography technology is designed to use extreme ultraviolet (EUV) light having a wavelength of 10˜14 nm.

However, the above-mentioned lithography technologies may still have many problems and difficulties in fabricating nanodevices.

In comparison with the above-mentioned lithography methods, nanoimprint lithography (NIL) technology has been intensively researched as an evolving technology capable of more economically mass-producing nanostructures and nanodevices.

The NIL technology includes pressing a surface of a semiconductor substrate coated with resist materials using a template or stamp on which nanometer scale structures each having a size of 100 nm or less are imprinted, such that a pattern of the template or stamp can be transferred to a material layer such as resin.

Compared with a conventional method for forming a resist pattern using general argon-fluoride (ArF) laser lithography or the like, the NIL technology can easily mass-produce many more nanodevices at lower costs.

### SUMMARY

Various embodiments of the present disclosure are directed to providing a semiconductor device and a method for forming the same that substantially address one or more problems caused due to limitations and disadvantages of the related art.

Embodiments of the present disclosure relate to a nanoimprint lithography (NIL) technology based on spin coating.

In accordance with an embodiment of the present disclosure, a semiconductor device may include a transfer-receiving substrate having a high region and a low region that are different in top-surface height from each other, a transfer-receiving pattern layer formed over the high region and the low region of the transfer-receiving substrate, in a manner that a top surface of the transfer-receiving pattern layer in the high region is planarized and a top surface of the transfer-receiving pattern layer in the low region is provided with a concave-convex pattern, and a planarization layer formed to gapfill the concave-convex pattern in a manner that a top surface of the planarization layer in the high region and a top surface of the planarization layer in the low region are planarized at a substantially same level.

In accordance with another embodiment of the present disclosure, a method for forming a semiconductor device may include forming a photocurable resin layer over a transfer-receiving substrate including a high region and a low region that are different in top-surface height from each other, arranging a template in which a transferring pattern is formed in some portions of a pattern surface, and the transfer-receiving substrate, so that the transferring pattern is arranged to face the low region, pressing the photocurable resin layer using the template to imprint the transferring pattern on the photocurable resin, curing the photocurable resin layer, isolating the template from the photocurable resin layer to form a transfer-receiving pattern layer in which a concave-convex pattern is formed only over the low region, and forming a planarization layer over the transfer-receiving pattern layer.

It is to be understood that both the foregoing general description and the following detailed description of the present disclosure are illustrative and explanatory and are intended to provide further explanation of the disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a cross-sectional view illustrating a semiconductor device including a planarization structure based on nanoimprint lithography (NIL) technology according to an embodiment of the present disclosure.

FIGS. 2A and 2B are views illustrating shapes of imprinted concave-convex patterns according to an embodiment of the present disclosure.

FIGS. 3 to 7 are views illustrating a planarization method according to an embodiment of the present disclosure.

### DESCRIPTION OF EMBODIMENTS

Various embodiments of the present invention are described below in more detail with reference to the accompanying drawings. We note, however, that the present invention may be embodied in different forms and variations, and should not be construed as being limited to the embodiments set forth herein. Rather, the described embodiments are provided so that this disclosure will be thorough and complete, and will fully convey the present invention to those skilled in the art to which this invention pertains. Throughout the disclosure, like reference numerals refer to like parts throughout the various figures and embodiments of the present invention.

It is noted that reference to “an embodiment,” “another embodiment” or the like does not necessarily mean only one embodiment, and different references to any such phrase are not necessarily to the same embodiment(s).

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to clearly illustrate features of the embodiments.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present. Communication between two elements, whether directly or indirectly connected/coupled, may be wired or wireless, unless stated or the context indicates otherwise.

As used herein, singular forms may include the plural forms as well and vice versa, unless the context clearly indicates otherwise. The articles ‘a’ and ‘an’ as used in this application and the appended claims should generally be construed to mean ‘one or more’ unless specified otherwise or clear from context to be directed to a singular form.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Hereinafter, the various embodiments of the present invention will be described in detail with reference to the attached drawings.

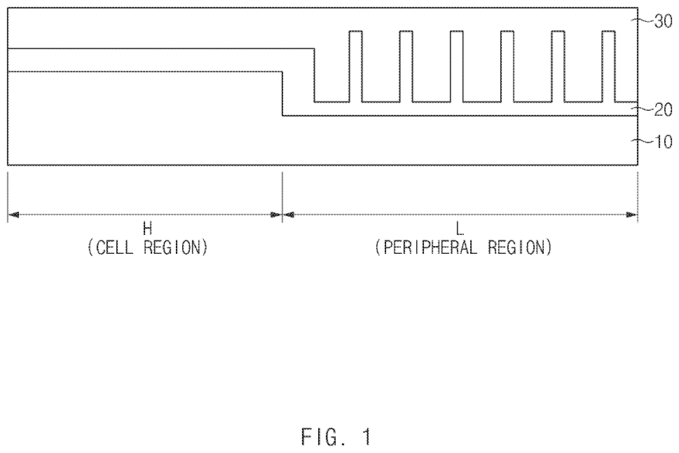

FIG. 1 is a cross-sectional view illustrating a semiconductor device including a planarization structure based on nanoimprint lithography (NIL) technology according to an embodiment of the present disclosure.

Referring to FIG. 1, the semiconductor device may include a transfer-receiving substrate 10, a transfer-receiving pattern layer 20, and a planarization layer 30.

The transfer-receiving substrate 10 may be any suitable substrate in which a planarization process based on spin-coating-based NIL technology can be carried out. The transfer-receiving substrate 10 may include a semiconductor wafer in which lower structures (e.g., semiconductor integrated circuits (ICs) including transistors and lines) needed to perform predefined operations are formed.

For example, in an embodiment, the transfer-receiving substrate 10 may include a cell region in which memory cells to store data therein are formed and a peripheral region in which logic circuits to write or read data in or from the memory cells are formed. In another embodiment, the transfer-receiving substrate 10 may include a pixel region provided with pixels and a peripheral region. The pixels may be configured to capture light for image sensing and to output light signals corresponding to the captured light. The peripheral region may be provided with logic circuits configured to process the light signals from the pixels.

The transfer-receiving substrate 10 may include a stepped structure having different heights in respective regions. For example, the transfer-receiving substrate 10 may include a stepped structure in which the cell region is different in height from the peripheral region due to a structural difference between the cell region and the peripheral region.

A high-height region will hereinafter be referred to as a high region (H), and a low-height region will hereinafter be referred to as a low region (L). Although in the illustrated embodiment of FIG. 1. the high region (H) is defined as the cell region and the low region (L) is defined as the peripheral region in FIG. 1 for convenience of description, the scope or spirit of the present disclosure is not limited thereto, and the positions of the cell region and the peripheral region may be interchanged according to a fabrication process of the semiconductor IC formed in the transfer-receiving substrate 10. Also, although in the embodiment of FIG. 1 there is illustrated one high region and one low region only, it is noted that the invention is not limited in this way, and that in other embodiments a plurality of high regions and/or a plurality of low regions may be employed.

The transfer-receiving pattern layer 20 may be formed over the transfer-receiving substrate 10.

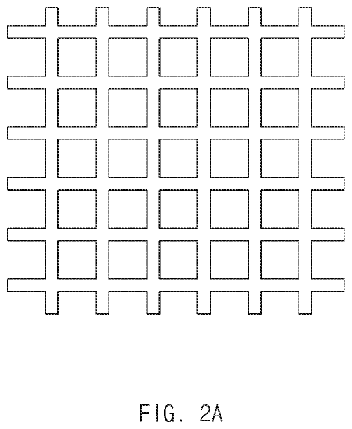

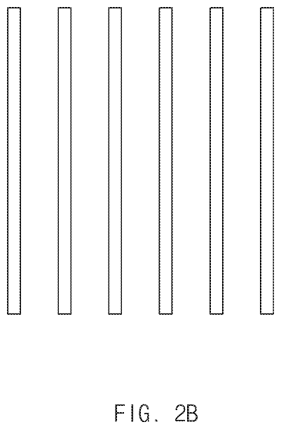

The transfer-receiving pattern layer 20 may be any suitable photocurable resin layer. The transfer-receiving pattern layer 20 may be any suitable photocurable resin layer onto which a transferring pattern of a template can be transferred. In the described embodiment, the photocurable resin may be a photoresist material. The transfer-receiving pattern layer 20 may be formed on the high region (H) and the low region (L) of the transfer-receiving substrate 10. Whereas a top surface of the transfer-receiving pattern layer 20 is planarized in the high region (H), a top surface of the transfer-receiving pattern layer 20 may be formed in a concave-convex shape in the low region (L). That is, the top surface of the transfer-receiving pattern layer 20 according to the embodiment may be planarized in the high region (H), and may be formed in a concave-convex shape in the low region (L). In this case, the concave-convex pattern may include, for example, a grid pattern shown in FIG. 2A or a line & space pattern shown in FIG. 2B.

In the transfer-receiving pattern layer 20, as illustrated in the embodiment of FIG. 1, the top surface of the concave-convex pattern may be higher in height than the planarized top surface of the transfer-receiving pattern layer 20 in the high region (H). That is, the concave-convex pattern may be formed to protrude upward, such that a height of the concave-convex pattern is higher than that of the top surface of the transfer-receiving pattern layer 20 formed in the high region (H).

The planarization layer 30 may be formed over the transfer-receiving pattern layer 20. A top surface of the planarization layer 30 may be planarized. A top surface in the high region (H) and a top surface in the low region are planarized at the same level. As illustrated in the embodiment of FIG. 1, the planarization layer 30 may cover the entirety of the transfer-receiving pattern layer 20 including filling the gaps of the concave-convex pattern of the transfer-receiving pattern layer 20.

In an embodiment, the planarization layer 30 may be a Spin on Carbon (SOC) layer.

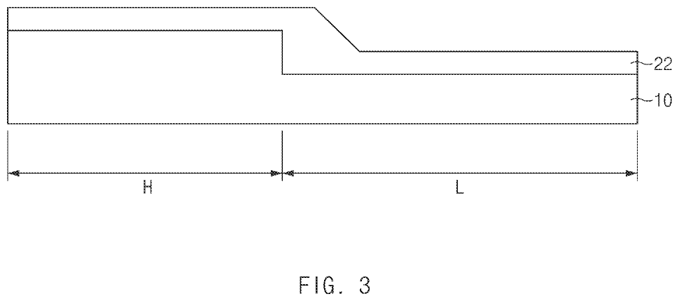

FIGS. 3 to 7 are views illustrating a planarization method according to an embodiment of the present disclosure. A method for forming the planarization structure shown in FIG. 1 will hereinafter be described with reference to the attached drawings.

Referring to FIG. 3, a resist layer 22 acting as an imprintable medium may be formed over the transfer-receiving substrate 10 including the high region (H) and the low region (L). The resist layer 22 may be formed as a curable coating layer. The resist layer 22 may be formed of a resin including photoresist elements, for example, a photoresist resin, such that the resist layer 22 is curable by irradiation with exposure light. The resist layer 22 may be formed of a photoresist material. The resist layer 22 may be formed by coating the imprintable medium over the transfer-receiving substrate 10 using the spin coating method.

The transfer-receiving substrate 10 may include a semiconductor wafer in which semiconductor integrated circuits may be formed. The transfer-receiving substrate 10 may be formed to have different heights in respective regions due to a structural difference between the semiconductor integrated circuits.

For example, if the transfer-receiving substrate 10 is a substrate provided with integrated circuits for memory devices, the cell region may be higher in height than the peripheral region in the transfer-receiving substrate 10. In this case, the high region (H) may be used as the cell region, and the low region (L) may be used as the peripheral region, as shown in FIG. 3. Alternatively, if a gate of each cell transistor formed in the cell region is formed as a buried gate buried in the semiconductor substrate, and a gate of each transistor formed in the peripheral region is formed in a planar shape protruding upward from the semiconductor substrate, the high region (H) may be used as the peripheral region and the low region (L) may be used as the cell region as necessary.

Prior to depositing the resist layer 22 over the transfer-receiving substrate 10, the substrate 10 may be surface-processed by an adhesion promoter such that the resist material can be well attached to the substrate 10. Any suitable adhesion promoter may be used.

After the resist layer 22 is deposited over the transfer-receiving substrate 10, the deposited resist layer 22 may be processed by soft baking. The soft baking may be performed at a temperature ranging from 60° C. to 100° C.

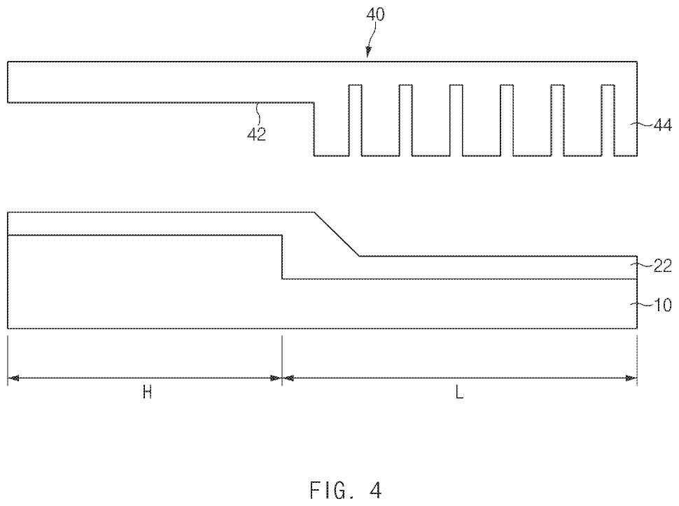

Referring to FIG. 4, the transfer-receiving substrate 10 provided with the resist layer 22 and the template 40, which is employed for nanoimprinting, may be arranged as shown prior to performing the nanoimprinting. The template 40 may be a member known as a stamp or mold. The template 40 may be formed when a transferring pattern 44 acting as a nanostructure to be transferred onto the resist layer 22 is formed over a pattern surface 42. The pattern surface may be a surface facing the resist layer 22 from among a plurality of surfaces of the template 40, and may be in contact with the resist layer 22 during the imprinting operation. The transferring pattern 44 formed over the pattern surface 42 may include a pattern that is capable of transferring a concave-convex pattern over the resist layer 22, for example, like the patterns shown in FIG. 2A or 2B.

According to the illustrated embodiment of FIG. 4, the transferring pattern 44 may be formed only partially over a specific region of the pattern surface 42. For example, the transferring pattern 44 may be formed only in a region of the pattern surface 42 of the template 40 facing the low region (L) of the transfer-receiving substrate 10. The remaining region of the pattern surface 42 which faces the high region (H) of the transfer-receiving substrate 10 may be substantially flat. In an embodiment, the transferring pattern 44 may be formed over the entire surface of the pattern surface 42 and may then be planarized over the portion of the pattern surface 42 which is opposite to the high region (H) of the transfer-receiving substrate 10. However, the invention is not limited in this way. For example, in another embodiment, the transferring pattern 44 may be formed only on the portion of the pattern surface 42 which is opposite to the low region (L) of the transfer-receiving substrate 10.

As illustrated in FIG. 4, the transfer-receiving substrate 10 and the template 40 may be arranged so that the transferring pattern 44 of the template 40 faces the low region (L) of the transfer-receiving substrate 10.

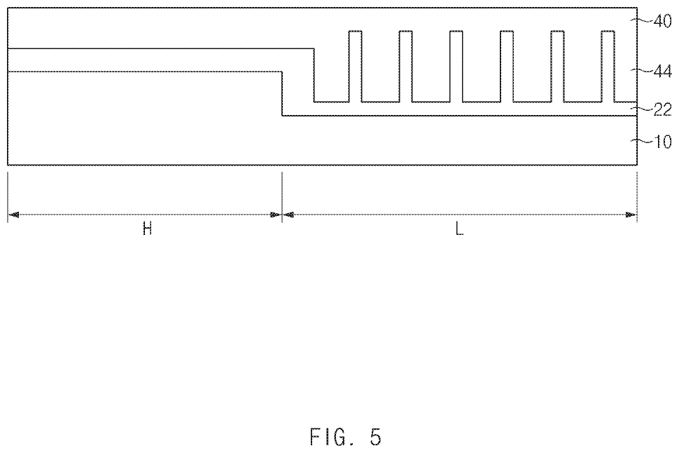

Referring to FIG. 5, the template 40 and the transfer-receiving substrate 10 may be brought closer to one another so that the transferring pattern 44 of the template 40 may contact the resist layer 22 which is on the transfer-receiving substrate 10 and force the resist material of the resist layer 22 to fill the recesses of the transferring pattern 44. Depending on design, the resist material may fill all or some of the recesses of the transferring pattern partially or completely. In the illustrated embodiment of FIG. 4, the resist material may fill all the recesses of the transferring pattern 44 completely.

In an embodiment, the template 40 may be moved down to contact the resist layer 22, and then the template 40 may be pressed against the resist layer 22 such that the resist material of the resist layer 22 may fill each recess of the transferring pattern 44 of the template.

The template 40 may be pressed with temperatures between a room temperature and 80° C. For example, in an embodiment, the template 40 may be kept at room temperature during the pressing step. In another embodiment, the template is heated to a temperature of about 80° C. and then is pressed. It is noted that this disclosure is not limited to any particular temperature of the template. The skilled person would understand that the desired temperature of the template may differ by design depending upon the particular resist material that is employed.

Subsequently, following the step in which the resist material has filled the recesses of the transferring pattern 44, the resist material may be cured. For example, curing may be performed by irradiating ultraviolet (UV) light onto the resist layer 22, such that the resist material in the resist layer 22 including the resist material inside the recesses of the transfer pattern 44 may be cured, preferably fully cured.

Fully curing of the resist layer 22 as this term is used in this disclosure means that the template 40 can be readily withdrawn in a subsequent step and that the shape of the pattern formed over the resist layer 22 during the curing step can remain unchanged after the template 40 is withdrawn. This way the transferring pattern 44 is effectively transferred on the resist layer 22.

The resist layer 22 may be irradiated with UV light through the template 40. Hence, it is noted that the template 40 may be made of any well-known suitable materials that allow the UV light to pass through.

Before the template 40 is brought in contact with the resist layer 22, the transferring pattern 44 of the template 40 may be surface treated with an anti-adhesion promoter so as to ensure that the surface of the transferring pattern 44 is free of impurities. The anti-adhesion promoter may also facilitate the withdrawal of the template 40 after the curing of the resist material of the resist layer 22 without damaging the formed pattern on the resist layer 22. Any suitable anti-adhesion promoter may be used.

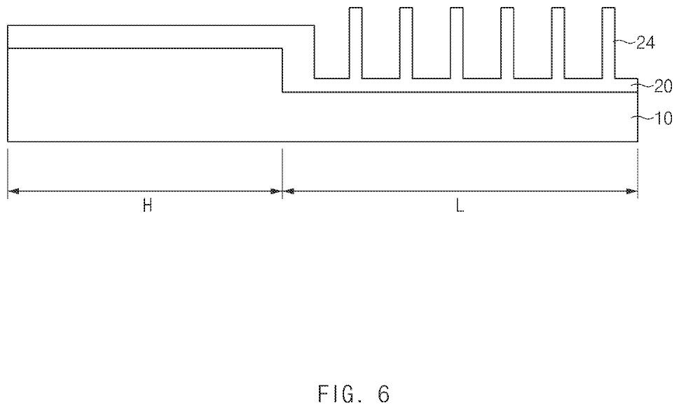

Referring to FIG. 6, after the imprinting of the transferring pattern 44 on the resist layer is performed, the template 40 may be isolated from the resist layer 22, such that the transfer-receiving pattern layer 20 may be formed over the transfer-receiving substrate 10.

For example, referring to FIG. 6, after the imprinting process of FIG. 5 is performed, the template 40 may be moved upward and away from the resist layer to become separated from the resist layer 22 so that the transfer-receiving pattern layer 20 may be formed over the transfer-receiving substrate 10.

In the described embodiment, the transfer-receiving pattern layer 20 may be formed over the high region (H) and the low region (L) of the transfer-receiving substrate 10. In more detail, the top surface of the transfer-receiving pattern layer 20 may be formed to be substantially planar in the high region (H), and may be formed in a concave-convex shape in the low region (L). That is, the transfer-receiving pattern layer 20 may include a concave-convex pattern 24 that is selectively formed only over the low region (L) of the transfer-receiving substrate 10. For example, the concave-convex pattern 24 may include the grid pattern shown in FIG. 2A or may include the line & space pattern shown in FIG. 2B. However, other patterns may also be used.

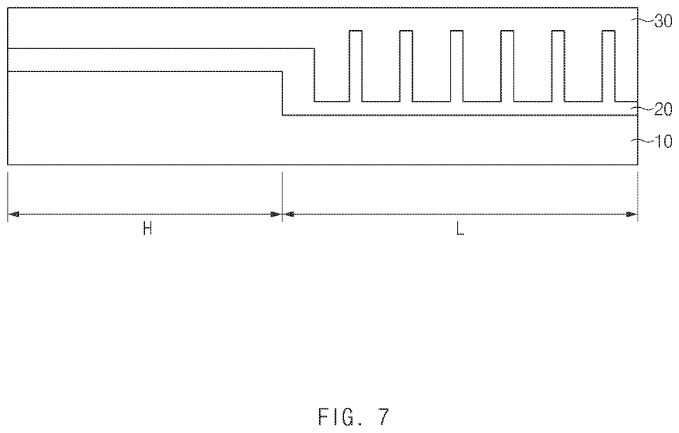

Referring to FIG. 7, an insulation film is formed to gap-fill the concave-convex pattern 24 over the transfer-receiving pattern layer 20 including the concave-convex pattern 24, and then the insulation film may be planarized to form the planarization layer 30. The insulation film may be planarized using, for example, Chemical Mechanical Polishing (CMP).

In the illustrated embodiment, the insulation film may be a Spin on Carbon (SOC) layer.

As is apparent from the above description, the semiconductor device and the method for forming the same according to the embodiments of the present disclosure may more easily perform planarization of the semiconductor device at a higher speed during the nanoimprint lithography (NIL) process based on spin coating, such that production costs of the semiconductor device can be reduced and throughput or performance of the semiconductor device can be improved.

Those skilled in the art will appreciate that the embodiments may be carried out in other specific ways than those set forth herein without departing from the spirit and essential characteristics of the disclosure. The above embodiments are therefore to be construed in all aspects as illustrative and not restrictive. The scope of the disclosure should be determined by the appended claims and their legal equivalents, not by the above description. Further, all changes coming within the meaning and equivalency range of the appended claims are intended to be embraced therein. In addition, those skilled in the art will understand that the claims that do not explicitly refer to one another in the appended claims may be presented in combination as an embodiment or included as a new claim by a subsequent amendment after the application is filed.

Although a number of illustrative embodiments have been described, it should be understood that numerous other modifications and embodiments can be devised by those skilled in the art that will fall within the spirit and scope of the principles of this disclosure. Particularly, numerous variations and modifications are possible in the component parts and/or arrangements which are within the scope of the disclosure, the drawings and the accompanying claims. In addition to variations and modifications in the component parts and/or arrangements, alternative uses will also be apparent to those skilled in the art. It is further noted that features described with one embodiment may also be employed with one or more features of another embodiment.

What is claimed is:

1. A semiconductor device comprising:
a transfer-receiving substrate having a high region and a low region that are different in top-surface height from each other;
a transfer-receiving pattern layer formed over the high region and the low region of the transfer-receiving substrate, in a manner that a top surface of the transfer-receiving pattern layer in the high region is planarized and a top surface of the transfer-receiving pattern layer in the low region is provided with a concave-convex pattern; and
a planarization layer formed to gapfill the concave-convex pattern in a manner that a top surface of the planarization layer in the high region and a top surface of the planarization layer in the low region are planarized at a substantially same level.

2. The semiconductor device according to claim 1, wherein the transfer-receiving substrate includes:
a cell region in which memory cells to store data are formed; and
a peripheral region in which logic circuits to write or read data in or from the memory cells are formed.

3. The semiconductor device according to claim 1, wherein:
the cell region is disposed in the high region; and
the peripheral region is disposed in the low region.

4. The semiconductor device according to claim 1, wherein the transfer-receiving substrate includes:
a pixel region in which pixels for capturing light for image sensing and outputting a light signal corresponding to the captured light are formed; and
a peripheral region in which logic circuits for processing light signals read out from the pixels are formed.

5. The semiconductor device according to claim 1, wherein the concave-convex pattern includes a grid pattern and/or a line and space pattern.

6. The semiconductor device according to claim 5, wherein the concave-convex pattern is formed to protrude upward such that a height of the concave-convex is higher than a height of the top surface of the transfer-receiving pattern layer formed in the high region.

7. The semiconductor device according to claim 1,
wherein the transfer-receiving pattern layer includes a photocurable resin layer, and
wherein the high region and the low region of the transfer-receiving substrate are a convex region having a convex top surface and a concave region having a concave top surface, respectively.

8. A method for forming a semiconductor device comprising:
forming a photocurable resin layer over a transfer-receiving substrate including a high region and a low region that are different in top-surface height from each other;
arranging a template in which a transferring pattern is formed in some portions of a pattern surface, and the transfer-receiving substrate, so that the transferring pattern is arranged to face the low region;
pressing the photocurable resin layer using the template to imprint the transferring pattern on the photocurable resin;
curing the photocurable resin layer;
isolating the template from the photocurable resin layer to form a transfer-receiving pattern layer in which a concave-convex pattern is formed only over the low region; and
forming a planarization layer over the transfer-receiving pattern layer.

9. The method according to claim 8, further comprising:
treating, prior to forming the photocurable resin layer over the transfer-receiving substrate, a surface of the transfer-receiving substrate with an adhesion promoter.

10. The method according to claim 8, further comprising:
performing, after forming the photocurable resin layer over the transfer-receiving substrate, soft baking of the photocurable resin layer.

11. The method according to claim 8, wherein the forming the planarization layer includes:
forming a Spin on Carbon (SOC) layer over the transfer-receiving pattern layer so as to gap-fill the concave-convex pattern.

12. The method according to claim 8, further comprising:
treating, prior to pressing the photocurable resin layer using the template, a surface of a transferring pattern using an anti-adhesion promoter.

13. The method according to claim 8, wherein the forming the transfer-receiving pattern layer includes:
planarizing a top surface of the photocurable resin layer in the high region; and
forming the concave-convex pattern over the photocurable resin layer in the low region.

14. The method according to claim 13, wherein the concave-convex pattern includes a grid pattern and/or a line and space pattern.

15. A semiconductor device comprising:
a transfer-receiving substrate having a high region and a low region;
a transfer-receiving pattern layer on the transfer-receiving substrate, the transfer-receiving pattern layer having a planarized top surface over the high region of the transfer-receiving substrate and concave-convex pattern over the low region of the transfer-receiving substrate; and
a Spin on Carbon (SOC) planarization layer formed to cover the transfer-receiving pattern layer with a top surface of the SOC planarization layer in the high region and a top surface of the SOC planarization layer in the low region at a substantially same level.
